(19) United States
(12) Patent Application Publication
(10) Pub. No.: US 2026/0190844 A1
(43) Pub. Date: Jul. 2, 2026

(54) DISPLAY DEVICE AND ELECTRONIC DEVICE INCLUDING THE SAME

(71) Applicant: Samsung Display Co., LTD., Yongin-si (KR)

(72) Inventors: AELY OH, Yongin-si (KR); KANG-WOO LEE, Yongin-si (KR)

(21) Appl. No.: 19/432,483

(22) Filed: Dec. 24, 2025

(30) Foreign Application Priority Data
Dec. 27, 2024 (KR) 10-2024-0198241

(51) Int. Cl. H10K 59/80

(52) U.S. Cl. CPC H10K 59/8794

(57) ABSTRACT

A display device includes a display module, a first heat dissipating layer disposed under the display module, and a second heat dissipating layer disposed under the first heat dissipating layer. The second heat dissipating layer includes: a second-first heat dissipating layer including a flat surface and a curved surface that extends from the flat surface and is concave, and a second-second heat dissipating layer including a flat portion that faces the flat surface and a bending portion that extends from the flat portion toward the curved surface. A first gap between an end of the curved surface and a portion of the bending portion closest to the end of the curved surface is smaller than a second gap between an end of the flat surface and an end of the flat portion. The second-first heat dissipating layer and the second-second heat dissipating layer include a metal.

This application claims priority to Korean Patent Application No. 10-2024-0198241, filed on December 27, 2024, and all the benefits accruing therefrom under 35 U.S.C. §119, the content of which in its entirety is herein incorporated by reference.

### BACKGROUND

Embodiments of the present disclosure described herein relate to a display device and an electronic device including the same.

An electronic device, such as a smart phone, a digital camera, a notebook computer, a car navigation unit, a smart television, or the like, which provides an image to a user includes a display device for displaying an image. The display device generates an image and provides the image to the user through a display screen.

The display device includes a display panel that displays an image, a driver that is connected to the display panel and that drives the display panel, a timing controller that controls operation timing of the driver, and a voltage generator that provides a driving voltage to the display panel.

When the display device operates, heat may be generated from the driver, the timing controller, and the voltage generator. The heat may degrade elements of the display panel. Accordingly, development of a heat dissipation technology for dissipating the heat generated from the display device is required.

### SUMMARY

Embodiments of the present disclosure provide a display device having an improved heat dissipation function and an electronic device including the same.

According to an embodiment, a display device includes a display module, a first heat dissipating layer disposed under the display module, and a second heat dissipating layer disposed under the first heat dissipating layer. The second heat dissipating layer includes a second-first heat dissipating layer including a flat surface and a curved surface that extends from the flat surface and is concave and a second-second heat dissipating layer including a flat portion that faces the flat surface and a bending portion that extends from the flat portion toward the curved surface, and a first gap between an end of the curved surface and a portion of the bending portion closest to the end of the curved surface is smaller than a second gap between an end of the flat surface and an end of the flat portion, and the second-first heat dissipating layer and the second-second heat dissipating layer include a metal.

According to an embodiment, an electronic device includes a camera, a display device that displays an image obtained by the camera, and a casing that accommodates the camera and the display device. The display device includes a display module, a first heat dissipating layer disposed under the display module, and a second heat dissipating layer disposed under the first heat dissipating layer. The second heat dissipating layer includes a second-first heat dissipating layer including a flat surface and a curved surface that extends from the flat surface and is concave and a second-second heat dissipating layer including a flat portion that faces the flat surface and a bending portion that extends from the flat portion toward the curved surface. A first gap between an end of the curved surface and a portion of the bending portion closest to the end of the curved surface is smaller than a second gap between an end of the flat surface and an end of the flat portion and the second-first heat dissipating layer and the second-second heat dissipating layer include a metal.

### BRIEF DESCRIPTION OF THE FIGURES

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of the electronic device illustrated in FIG. 1.

FIG. 3 is a block diagram of the electronic device illustrated in FIG. 2.

FIG. 4 is a sectional view taken along line I-I’ illustrated in FIG. 2.

FIG. 5 is a sectional view taken along line II-II’ illustrated in FIG. 2.

FIG. 6 is a view illustrating a cross-section of a display panel illustrated in FIG. 4.

FIG. 7 is a plan view of the display panel illustrated in FIG. 4.

FIG. 8 is a view illustrating a cross-section of the display panel corresponding to any one pixel illustrated in FIG. 7.

FIG. 9 is a sectional view taken along line III-III’ illustrated in FIG. 2, and illustrates a specific configuration of a second heat dissipating layer illustrated in FIG. 4.

FIG. 10 is a perspective view of the second heat dissipating layer illustrated in FIG. 9.

FIG. 11 is a sectional view illustrating a configuration of a second heat dissipating layer according to an embodiment of the present disclosure.

FIG. 12 is a sectional view illustrating a configuration of a second heat dissipating layer according to an embodiment of the present disclosure.

FIG. 13 is a sectional view illustrating a configuration of a second heat dissipating layer according to an embodiment of the present disclosure.

FIG. 14 is a view illustrating a configuration of a second heat dissipating layer according to an embodiment of the present disclosure.

FIG. 15 is a view illustrating a configuration of a second heat dissipating layer according to an embodiment of the present disclosure.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

As used herein, the term “and/or” includes all of one or more combinations defined by related components.

Terms such as “first”, “second”, “first-first”, “first-second”, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the present disclosure will be described with reference to the accompanying drawings.

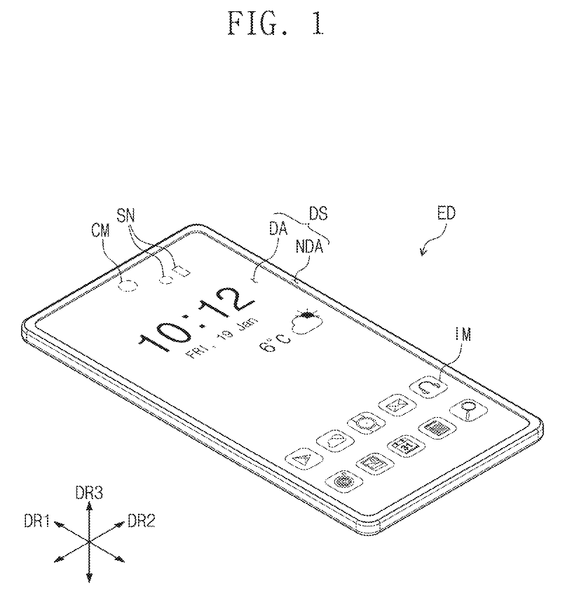

FIG. 1 is a perspective view of an electronic device according to an embodiment of the present disclosure.

Referring to FIG. 1, the electronic device ED according to an embodiment of the present disclosure may have long sides extending in a first direction DR1 and short sides extending in a second direction DR2 crossing the first direction DR1. The electronic device ED may have a quadrangular shape with rounded corners. For example, four corners of the electronic device ED may have a rounded shape. However, the shape of the electronic device ED is not limited to the shape illustrated in FIG. 1, and the electronic device ED may have various shapes.

Hereinafter, a direction substantially perpendicular to a plane defined by the first direction DR1 and the second direction DR2 is defined as a third direction DR3. The expression “when viewed from above the plane” used herein may mean that it is viewed in the third direction DR3. In addition, the meaning of “overlap” in this specification may refer to a state in which components are disposed to overlap each other when viewed from above the plane.

The upper surface of the electronic device ED may be defined as a display surface DS and may have a plane defined by the first direction DR1 and the second direction DR2. Images IM generated by the electronic device ED may be provided to a user through the display surface DS.

The display surface DS may include a display area DA and a non-display area NDA around the display area DA. The display area DA may display an image, and the non-display area NDA may not display an image. The non-display area NDA may surround the display area DA and may define the border of the electronic device ED that is printed in a certain color.

The electronic device ED may include a plurality of sensors SN and at least one camera CM. The sensors SN and the camera CA may be adjacent to the border of the electronic device ED. The sensors SN and the camera CM may be disposed in the display area DA adjacent to the non-display area NDA.

For example, the sensors SN may be proximity illuminance sensors. However, the types of the sensors SN are not limited thereto. The camera CM may take an external image.

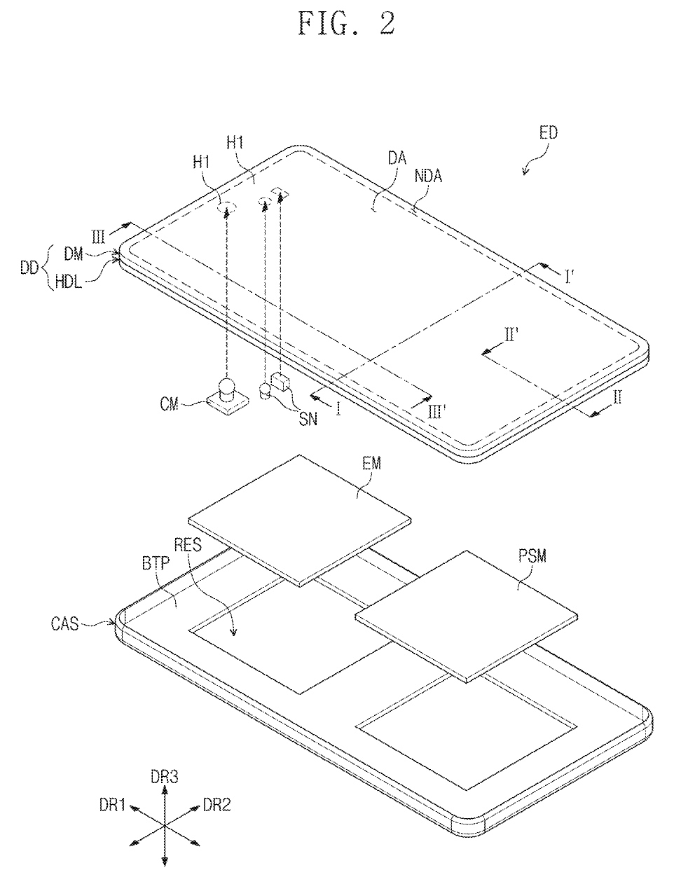

FIG. 2 is an exploded perspective view of the electronic device illustrated in FIG. 1.

Referring to FIG. 2, the electronic device ED may include a display device DD, the camera CA, the sensors SN, an electronic module EM, a power supply module PSM, and a casing CAS.

The display device DD may have long sides extending in the first direction DR1 and short sides extending in the second direction DR2 crossing the first direction DR1. The display device DD may have a quadrangular shape with rounded corners to correspond to the shape of the electronic device ED.

The display device DD may include a display area DA and a non-display area NDA surrounding the display area DA. The display area DA may display an image, and the non-display area NDA may not display an image. The display area DA and the non-display area NDA of the display device DD may correspond to the display area DA and the non-display area NDA of the electronic device ED, respectively, which are illustrated in FIG. 1.

The display device DD may include a display module DM and a heat dissipating layer HDL disposed under the display module DM. The display module DM may generate an image. The display module DM may have a plane defined by the first direction DR1 and the second direction DR2 and may extend longer in the first direction DR1 than in the second direction DR2.

The display module DM may include a display area DA that displays an image and a non-display area NDA that surrounds the display area DA and does not display an image. The display area DA and the non-display area NDA of the display module DM may correspond to the display area DA and the non-display area NDA of the display device DD, respectively.

The heat dissipating layer HDL may perform a heat dissipation function for dissipating heat generated from the display module DM. A specific configuration of the heat dissipating layer HDL will be described below in detail.

A first hole area H1 and second hole areas H2 may be defined in the display device DD. Although not illustrated, holes may be defined in the first hole area H1 and the second hole areas H2, respectively. The camera CM may be disposed in the hole defined in the first hole area H1, and the sensors SN may be disposed in the holes defined in the second hole areas H2.

The electronic module EM and the power supply module PSM may be disposed under the display device DD. Although not illustrated, the electronic module EM and the power supply module PSM may be connected with each other through a separate flexible circuit board. The electronic module EM may control an operation of the display device DD. The power supply module PSM may supply power to the electronic module EM.

The casing CAS may accommodate the display device DD, the camera CM, the sensors SN, the electronic module EM, and the power supply module PSM. The casing CAS may protect the display device DD, the electronic module EM, and the power supply module PSM. The electronic module EM and the power supply module PSM may be disposed in depressions RES, respectively, which are defined on a bottom portion BTP of the casing CAS.

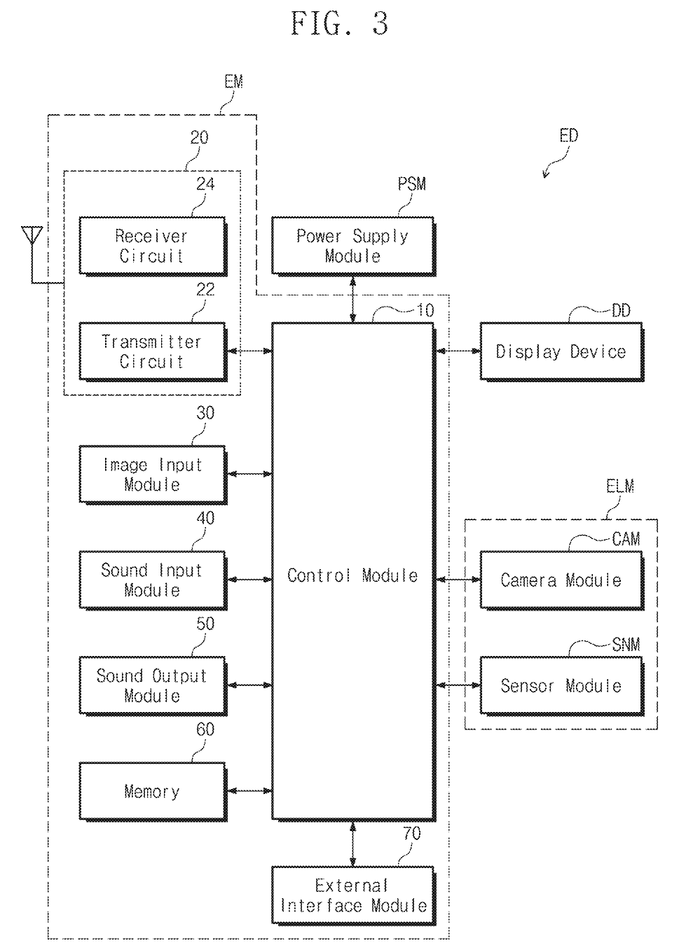

FIG. 3 is a block diagram of the electronic device illustrated in FIG. 2.

Referring to FIG. 3, the electronic device ED may include the electronic module EM, the power supply module PSM, the display device DD, and an electro-optical module ELM. The electronic module EM may include a control module 10, a wireless communication module 20, an image input module 30, a sound input module 40, a sound output module 50, a memory 60, and an external interface module 70. The modules may be mounted on a circuit board or may be electrically connected through a flexible circuit board. The electronic module EM may be electrically connected with the power supply module PSM.

The control module 10 may control overall operation of the electronic device ED. For example, the control module 10 may activate or deactivate the display device DD in response to a user input. The control module 10 may control the image input module 30, the sound input module 40, and the sound output module 50 in response to a user input. The control module 10 may include at least one microprocessor.

The wireless communication module 20 may transmit/receive wireless signals with another terminal using Bluetooth or Wi-Fi. The wireless communication module 20 may transmit/receive sound signals using a general communication line. The wireless communication module 20 may include a transmitter circuit 22 that modulates a signal to be transmitted and transmits the modulated signal and a receiver circuit 24 that demodulates a received signal.

The image input module 30 may process an image signal to covert the image signal into image data capable of being displayed on the display device DD. The sound input module 40 may receive an external sound signal through a microphone in a voice recording mode or a voice recognition mode and may convert the external sound signal into electrical voice data. The sound output module 50 may convert sound data received from the wireless communication module 20 or sound data stored in the memory 60 and may output the converted sound data to the outside.

The external interface module 70 may serve as an interface connected to an external charger, a wired/wireless data port, and a card socket (e.g., a memory card or a SIM/UIM card).

The power supply module PSM may supply power required for overall operation of the electronic device ED. The power supply module PSM may include a conventional battery device.

The electro-optical module ELM may be an electronic part that outputs or receives an optical signal. The electro-optical module ELM may transmit or receive an optical signal through a partial area of the display device DD.

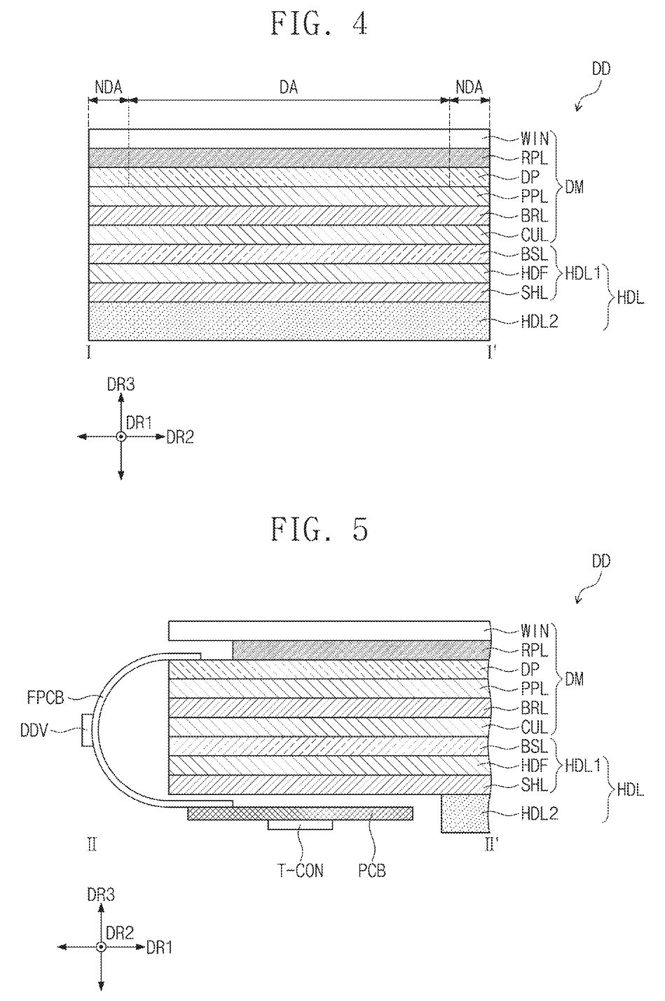

In this embodiment, the electro-optical module ELM may include a camera module CAM and a sensor module SNM. The camera module CAM may include the camera CA illustrated in FIG. 2. The sensor module SNM may include the sensors SN illustrated in FIG. 2. Accordingly, the electro-optical module ELM may include the camera CM and the sensors SN and may be disposed under the display device DD illustrated in FIG. 4. An image obtained by the camera CM may be displayed through the display device DD under the control of the electronic module EM.

The electro-optical module ELM may receive an optical signal (e.g., an external image) through the first hole area H1. The electro-optical module ELM may transmit and receive optical signals (e.g., transmission/reception signals for proximity sensing) through the second hole areas H2. The electro-optical module ELM may be disposed within the electronic module EM. Alternatively, the electro-optical module ELM may be manufactured as a separate module and may be accommodated in the above-described casing CAS.

FIG. 4 is a sectional view taken along line I-I’ illustrated in FIG. 2.

Referring to FIG. 4, the display module DM may include a display panel DP, an anti-reflective layer RPL, a window WIN, a panel protection layer PPL, a barrier layer BRL, and a cushion layer CUL.

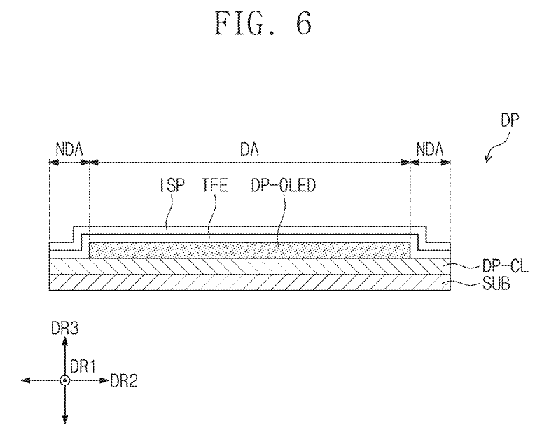

The display panel DP may generate an image. The display panel DP may include a display area DA that displays an image and a non-display area NDA that is disposed around the display area DA and that does not display an image. The display area DA and the non-display area NDA of the display panel DP may correspond to the display area DA and the non-display area NDA of the display module DM, respectively. The display panel DP may include an input sensing part ISP (illustrated in FIG. 6) for sensing an external input.

The display panel DP according to an embodiment of the present disclosure may be an emissive display panel. For example, the display panel DP may be an organic light emitting display panel or an inorganic light emitting display panel. An emissive layer of the organic light emitting display panel may include an organic luminescent material. An emissive layer of the inorganic light emitting display panel may include a quantum dot and a quantum rod. Hereinafter, it will be exemplified that the display panel DP is an organic light emitting display panel.

The anti-reflective layer RPL may be disposed over the display panel DP. The anti-reflective layer RPL may be defined as a film for preventing the reflection of external light. The anti-reflective layer RPL may decrease the reflectance of external light incident toward the display panel DP from the outside.

When the external light travelling toward the display panel DP is reflected from the display panel DP and provided back to the user, the user may visually recognize the external light as in a mirror. To prevent this phenomenon, the anti-reflective layer RPL may include a plurality of color filters that display the same colors as pixels.

The color filters may filter the external light into the same colors as those of the pixels. In this case, the external light may not be visible to the user. However, without being limited thereto, the anti-reflective layer RPL may include a phase retarder and/or a polarizer to decrease the reflectance of the external light.

The window WIN may be disposed on the anti-reflective layer RPL. The window WIN may protect the display panel DP and the anti-reflective layer RPL from external scratches. The window WIN may have a property of being optically clear. The window WIN may include glass. However, without being limited thereto, the window WIN may include a synthetic resin film.

The panel protection layer PPL may be disposed under the display panel DP. The panel protection layer PPL may protect the bottom of the display panel DP. The panel protection layer PPL may include a flexible plastic material. For example, the panel protection layer PPL may include polyethylene terephthalate (PET).

The barrier layer BRL may be disposed under the panel protection layer PPL. The barrier layer BRL may increase resistance to a compressive force caused by external pressing. Accordingly, the barrier layer BRL may serve to prevent deformation of the display panel DP. The barrier layer BRL may include a flexible plastic material such as polyimide (PI) or polyethylene terephthalate (PET).

The barrier layer BRL may have a color that absorbs light. The barrier layer BRL may be black in color. In this case, components disposed under the barrier layer BRL may not be visible when the display device DD is viewed from above the display device DD.

The cushion layer CUL may be disposed under the barrier layer BRL. The cushion layer CUL may protect the display panel DP by absorbing external impact applied to the bottom of the display module DM. The cushion layer CUL may include an elastic foam sheet. The cushion layer CUL may include expanded foam, a sponge, poly-urethane, or thermoplastic poly-urethane.

The heat dissipating layer HDL may be disposed under the cushion layer CUL. The heat dissipating layer HDL may perform a heat dissipation function. The heat dissipating layer HDL may include a first heat dissipating layer HDL1 disposed under the display module DM and a second heat dissipating layer HDL2 disposed under the first heat dissipating layer HDL1.

The first heat dissipating layer HDL1 may include a base layer BSL, a heat dissipating film HDF, and a shielding layer SHL. The base layer BSL may be disposed under the display module DM. Specifically, the base layer BSL may be disposed under the cushion layer CUL. The base layer BSL may include a plastic material such as polyimide (PI) or polyethylene terephthalate (PET).

The heat dissipating film HDF may be disposed under the base layer BSL. The heat dissipating film HDF may perform a heat dissipation function. For example, the heat dissipating film HDF may include graphite, but the material of the heat dissipating film HDF is not limited thereto.

The shielding layer SHL may be disposed under the heat dissipating film HDF. The shielding layer SHL may shield external electromagnetic waves. To shield the external electromagnetic waves, the shielding layer SHL may include copper. However, without being limited thereto, the shielding layer SHL may include various conductive materials to shield the external electromagnetic waves. Additionally, the shielding layer SHL may perform a heat dissipation function.

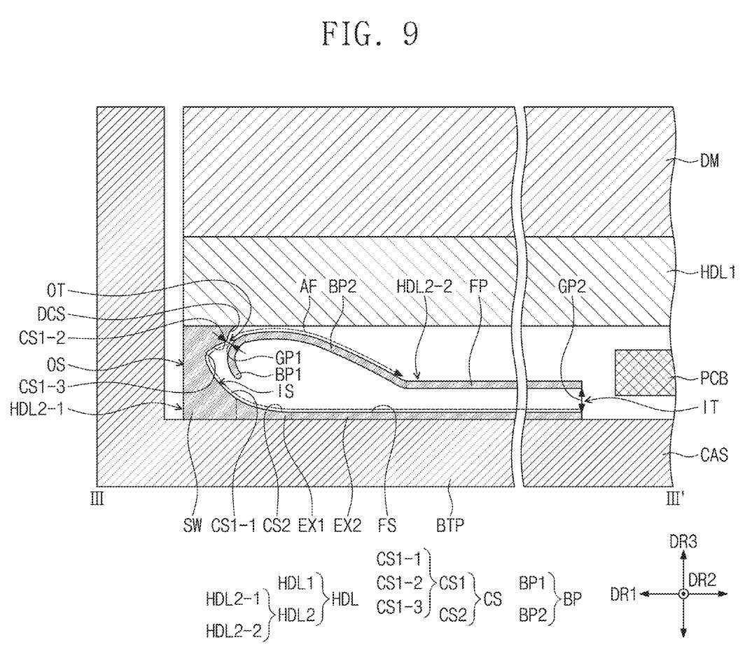

The second heat dissipating layer HDL2 may perform a heat dissipation function. The second heat dissipating layer HDL2 may circulate air. For convenience of description, for example, the second heat dissipating layer HDL2 having a rectangular cross-sectional structure is illustrated in FIG. 4. However, substantially, the second heat dissipating layer HDL2 may have a certain shape for circulating air. A detailed structure of the second heat dissipating layer HDL2 will be described below in detail with reference to FIG. 9.

Although not illustrated, the display device DD may further include a plurality of adhesive layers for bonding the display panel DP, the anti-reflective layer RPL, the window WIN, the panel protection layer PPL, the barrier layer BRL, the cushion layer CUL, the first heat dissipating layer HDL1, and the second heat dissipating layer HDL2. The adhesive layers may include a transparent adhesive such as a pressure sensitive adhesive (PSA) or an optically clear adhesive (OCA), but the types of the adhesive layers are not limited thereto.

In addition, although not illustrated, the holes defined in the first hole area H1 and the second hole areas H2 described above may be defined in the display module DM and the first heat dissipating layer HDL1.

FIG. 5 is a sectional view taken along line II-II’ illustrated in FIG. 2.

Referring to FIG. 5, the display device DD may include a flexible circuit board FPCB, a data driver DDV, a printed circuit board PCB, and a timing controller T-CON.

One side of the flexible circuit board FPCB may be connected to the display panel DP. The data driver DDV may be mounted on the upper surface of the flexible circuit board FPCB. The data driver DDV may be connected to the display panel DP through the flexible circuit board FPCB.

An opposite side of the flexible circuit board FPCB may be connected to the printed circuit board PCB. The data driver DDV may be connected to the printed circuit board PCB through the flexible circuit board FPCB. The printed circuit board PCB may be connected to the display panel DP through the flexible circuit board FPCB.

The timing controller T-CON may be mounted on the upper surface of the printed circuit board PCB. The data driver DDV may be connected to the timing controller T-CON through the flexible circuit board FPCB and the printed circuit board PCB.

The flexible circuit board FPCB may be bent, and the printed circuit board PCB and the timing controller T-CON may be disposed under the first heat dissipating layer HDL1. Accordingly, the printed circuit board PCB may be disposed under the display panel DP. The second heat dissipating layer HDL2 may extend adjacent to a side surface of the printed circuit board PCB.

Although not illustrated, the printed circuit board FPCB may be attached to the lower surface of the first heat dissipating layer HDL1 through an adhesive layer.

FIG. 6 is a view illustrating a cross-section of the display panel illustrated in FIG. 4.

For example, in FIG. 6, a cross-section of the display panel DP viewed in the first direction DR1 is illustrated.

Referring to FIG. 6, the display panel DP may include a substrate SUB, a circuit element layer DP-CL disposed on the substrate SUB, a display element layer DP-OLED disposed on the circuit element layer DP-CL, a thin film encapsulation layer TFE disposed on the display element layer DP-OLED, and the input sensing part ISP disposed on the thin film encapsulation layer TFE. The display element layer DP-OLED may be disposed on the display area DA.

The substrate SUB may include a display area DA and a non-display area NDA around the display area DA. The substrate SUB may include a flexible plastic material. For example, the substrate SUB may include polyimide (PI).

A plurality of pixels may be disposed in the circuit element layer DP-CL and the display element layer DP-OLED. Each of the pixels may include transistors disposed in the circuit element layer DP-CL and a light emitting element disposed in the display element layer DP-OLED and connected to the transistors. The light emitting elements may be driven by the transistors to display an image.

The thin film encapsulation layer TFE may be disposed on the circuit element layer DP-CL to cover the display element layer DP-OLED. The thin film encapsulation layer TFE may include an inorganic layer, an organic layer, and an inorganic layer sequentially stacked one above another. The inorganic layers may include an inorganic material and may protect the pixels from moisture/oxygen. The organic layer may include an organic material and may protect the pixels PX from foreign matter such as dust particles.

The input sensing part ISP may include a plurality of sensors (not illustrated) for sensing an external input. The sensors may sense the external input in a capacitance type. The external input may include various types of inputs such as a part of the user’s body, light, heat, a pen, pressure, and the like.

The input sensing part ISP may be directly manufactured on the thin film encapsulation layer TFE when the display panel DP is manufactured. However, without being limited thereto, the input sensing part ISP may be manufactured as a panel separate from the display panel DP and may be attached to the display panel DP by an adhesive layer.

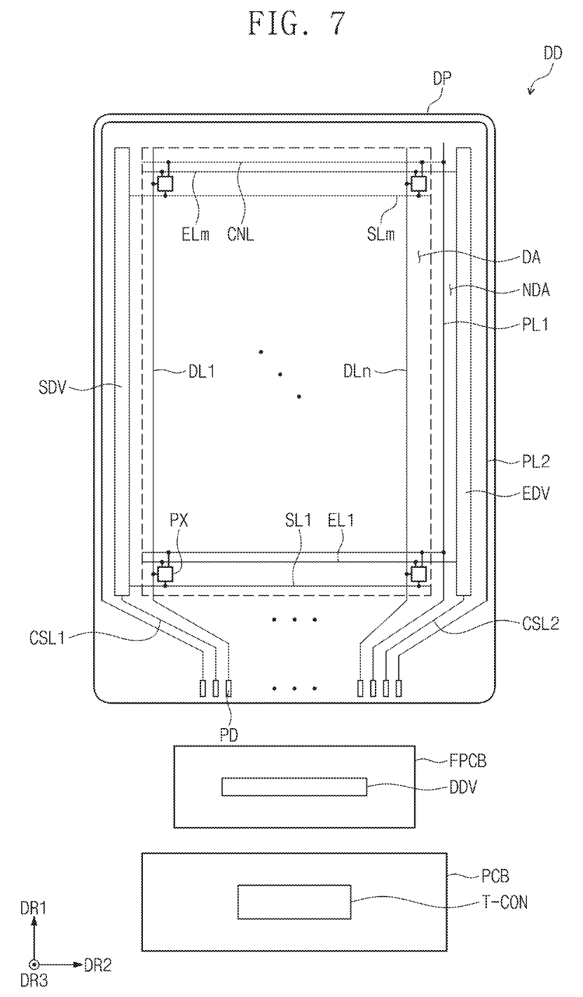

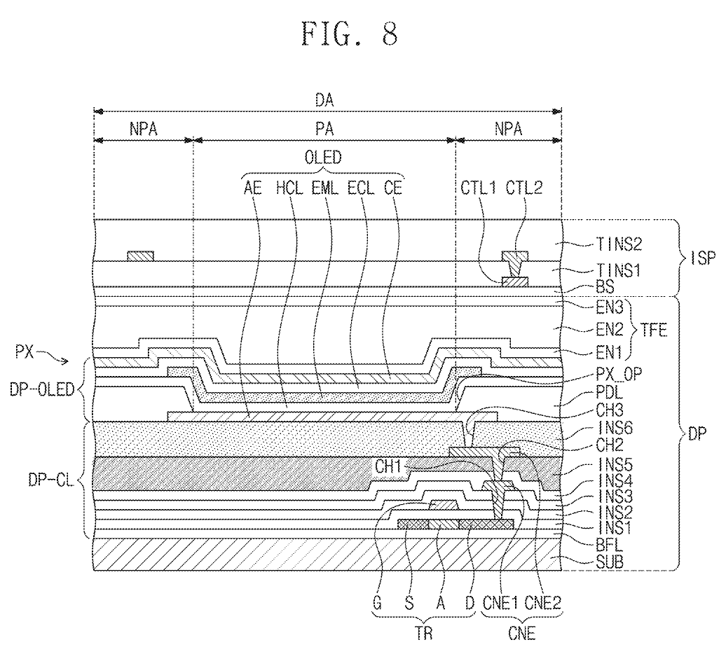

FIG. 7 is a plan view of the display panel illustrated in FIG. 4.

Referring to FIG. 7, the display device DD may include the display panel DP, a scan driver SDV, the data driver DDV, a light emission driver EDV, a plurality of pads PD, the timing controller T-CON, the flexible circuit board FPCB, and the printed circuit board PCB.

The display panel DP may have a rounded quadrangular shape with long sides extending in the first direction DR1 and short sides extending in the second direction DR2. The display panel DP may include the display area DA and the non-display area NDA surrounding the display area DA.

The display panel DP may include the plurality of pixels PX, a plurality of scan lines SL1 to SLm, a plurality of data lines DL1 to DLn, a plurality of light emission lines EL1 to ELm, a first control line CSL1, a second control line CSL2, a first power line PL1, a second power line PL2, and a plurality of connecting lines CNL. “m” and “n” are natural numbers.

The pixels PX may be disposed in the display area DA. The scan driver SDV and the light emission driver EDV may be disposed in the non-display areas NDA adjacent to opposite sides of the display panel DP that face away from each other in the second direction DR2.

The data driver DDV may be disposed on the flexible circuit board FPCB. The data driver DDV may be manufactured in the form of an integrated circuit chip and may be mounted on the flexible circuit board FPCB.

The pads PD may be disposed on the display panel DP. The pads PD may be adjacent to the lower end of the display panel DP. The pads PD may be arranged in the second direction DR2.

The scan lines SL1 to SLm may extend in the second direction DR2 and may be connected to the pixels PX and the scan driver SDV. The light emission lines EL1 to ELm may extend in the second direction DR2 and may be connected to the pixels PX and the light emission driver EDV. The data lines DL1 to DLn may extend in the first direction DR1 and may be connected to the pixels PX and the pads PD.

The flexible circuit board FPCB may be disposed in the non-display area NDA adjacent to one of the short sides of the display panel DP. For example, the flexible circuit board FPCB may be connected to the pads PD. Accordingly, the flexible circuit board FPCB may be connected to the non-display area NDA adjacent to the lower end of the display panel DP when viewed from above the plane.

The data driver DDV may be connected to the pads PD through the flexible circuit board FPCB. That is, the data driver DDV may be connected to the display panel DP through the flexible circuit board FPCB. However, without being limited thereto, the data driver DDV may be directly disposed on the non-display area NDA of the display panel DP. The pads PD connected to the data lines DL1 to DLn may be connected to the data driver DDV through the flexible circuit board FPCB.

Although not illustrated, the flexible circuit board FPCB may include a plurality of lines connected to the data driver DDV. The lines may be connected to a plurality of chip pads disposed on the flexible circuit board FPCB. The chip pads may be connected to the pads PD so that the flexible circuit board FPCB and the data driver DDV may be connected to the display panel DP.

The first power line PL1 may extend in the first direction DR1 and may be disposed in the non-display area NDA. The first power line PL1 may be disposed between the display area DA and the light emission driver EDV.

The connecting lines CNL may extend in the second direction DR2 and may be arranged in the first direction DR1. The connecting lines CNL may be connected to the first power line PL1 and the pixels PX. A first voltage may be applied to the pixels PX through the first power line PL1 and the connecting lines CNL connected with each other.

The second power line PL2 may be disposed in the non-display area NDA and may extend along the long sides of the display panel DP and the other short side of the display panel DP where the data driver DDV is not disposed. The second power line PL2 may be disposed outward of the scan driver SDV and the light emission driver EDV.

Although not illustrated, the second power line PL2 may extend toward the display area DA and may be connected to the pixels PX. A second voltage having a lower level than the first voltage may be applied to the pixels PX through the second power line PL2.

The first control line CSL1 may be connected to the scan driver SDV and may extend toward the lower end of the display panel DP. The second control line CSL2 may be connected to the light emission driver EDV and may extend toward the lower end of the display panel DP.

The data lines DL1 to DLn, the first power line PL1, the second power line PL2, the first control line CSL1, and the second control line CSL2 may be connected to the pads PD, respectively.

The timing controller T-CON may be disposed on the printed circuit board PCB. The timing controller T-CON may be manufactured in the form of an integrated circuit chip and may be mounted on the printed circuit board PCB. The one side of the flexible circuit board FPCB may be connected to the display panel DP, and the opposite side of the flexible circuit board FPCB may be connected to the printed circuit board PCB.

The timing controller T-CON may be connected to the data driver DDV through the printed circuit board PCB. In addition, the timing controller T-CON may be connected to the scan driver SDV and the light emission driver EDV through the printed circuit board PCB and the flexible circuit board FPCB. The timing controller T-CON may control operations of the scan driver SDV, the data driver DDV, and the light emission driver EDV.

Although not illustrated, the display device DD may further include a voltage generator for generating the first voltage and the second voltage. The voltage generator may be disposed on the printed circuit board PCB.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The light emission driver EDV may generate a plurality of light emission signals, and the light emission signals may be applied to the pixels PX through the light emission lines EL1 to ELm.

The pixels PX may receive the data voltages in response to the scan signals. The pixels PX may display an image by emitting light having luminance corresponding to the data voltages in response to the light emission signals.

Heat may be generated from the data driver DDV, the timing controller T-CON, and the voltage generator when the display device DD operates. The heat may be dissipated by the heat dissipating layer HDL described above.

FIG. 8 is a view illustrating a cross-section of the display panel corresponding to any one pixel illustrated in FIG. 7.

Referring to FIG. 8, the display panel DP may include a pixel PX, and the pixel PX may include a transistor TR and a light emitting element OLED. The light emitting element OLED may include a first electrode AE (or, an anode), a second electrode CE (or, a cathode), a hole control layer HCL, an electron control layer ECL, and an emissive layer EML.

The transistor TR and the light emitting element OLED may be disposed on the substrate SUB. Although one transistor TR is illustrated as an example, the pixel PX may include a plurality of transistors and at least one capacitor for driving the light emitting element OLED.

The display area DA may include an emissive area PA corresponding to each of the pixels PX and a non-emissive area NPA around the emissive area PA. The light emitting element OLED may be disposed in the emissive area PA.

A buffer layer BFL may be disposed on the substrate SUB. The buffer layer BFL may be an inorganic layer. A semiconductor pattern may be disposed on the buffer layer BFL. The semiconductor pattern may include poly silicon, amorphous silicon, or metal oxide.

The semiconductor pattern may be doped with an N-type dopant or a P-type dopant. The semiconductor pattern may include highly-doped areas and a lightly-doped area. The highly-doped areas may have a higher conductivity than the lightly-doped area and may substantially serve as a source electrode and a drain electrode of the transistor TR. The lightly-doped area may substantially correspond to an active (or, channel) area of the transistor TR.

The source S, the active area A, and the drain D of the transistor TR may be formed from the semiconductor pattern. A first insulating layer INS1 may be disposed on the semiconductor pattern. The gate G of the transistor TR may be disposed on the first insulating layer INS1. A second insulating layer INS2 may be disposed on the gate G. A third insulating layer INS3 may be disposed on the second insulating layer INS2.

A connecting electrode CNE may include a first connecting electrode CNE1 and a second connecting electrode CNE2 to connect the transistor TR and the light emitting element OLED. The first connecting electrode CNE1 may be disposed on the third insulating layer INS3 and may be connected to the drain D through a first contact hole CH1 defined in the first to third insulating layers INS1 to INS3.

A fourth insulating layer INS4 may be disposed on the first connecting electrode CNE1. A fifth insulating layer INS5 may be disposed on the fourth insulating layer INS4. The second connecting electrode CNE2 may be disposed on the fifth insulating layer INS5. The second connecting electrode CNE2 may be connected to the first connecting electrode CNE1 through a second contact hole CH2 defined in the fourth insulating layer INS4 and the fifth insulating layer INS5.

A sixth insulating layer INS6 may be disposed on the second connecting electrode CNE2. The layers from the buffer layer BFL to the sixth insulating layer INS6 may be defined as the circuit element layer DP-CL. The first to sixth insulating layers INS1 to INS6 may be inorganic layers or organic layers.

The first electrode AE may be disposed on the sixth insulating layer INS6. The first electrode AE may be connected to the second connecting electrode CNE2 through a third contact hole CH3 defined in the sixth insulating layer INS6. A pixel defining layer PDL having an opening PX_OP defined therein to expose a certain portion of the first electrode AE may be disposed on the first electrode AE and the sixth insulating layer INS6.

The hole control layer HCL may be disposed on the first electrode AE and the pixel defining layer PDL. The hole control layer HCL may include a hole transport layer and a hole injection layer.

The emissive layer EML may be disposed on the hole control layer HCL. The emissive layer EML may be disposed in an area corresponding to the opening PX_OP. The emissive layer EML may include an organic material and/or an inorganic material. The emissive layer EML may generate one of red light, green light, and blue light.

The electron control layer ECL may be disposed on the emissive layer EML and the hole control layer HCL. The electron control layer ECL may include an electron transport layer and an electron injection layer. The hole control layer HCL and the electron control layer ECL may be commonly disposed in the emissive area PA and the non-emissive area NPA.

The second electrode CE may be disposed on the electron control layer ECL. The second electrode CE may be commonly disposed in the pixels PX. The layer in which the light emitting element OLED is disposed may be defined as the display element layer DP-OLED.

The thin film encapsulation layer TFE may be disposed on the second electrode CE and may cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first encapsulation layer EN1 and the third encapsulation layer EN3 may include an inorganic insulating layer and may protect the pixel PX from moisture/oxygen. The second encapsulation layer EN2 may include an organic insulating layer and may protect the pixel PX from foreign matter such as dust particles.

The first voltage may be applied to the first electrode AE through the transistor TR, and the second voltage having a lower level than the first voltage may be applied to the second electrode CE. Holes and electrons injected into the emissive layer EML may be combined to form excitons, and as the excitons transition to a ground state, the light emitting element OLED may emit light.

The layers from the substrate SUB to the thin film encapsulation layer TFE may be defined as the display panel DP. The input sensing part ISP may be disposed on the thin film encapsulation layer TFE. The input sensing part ISP may be directly manufactured on the upper surface of the thin film encapsulation layer TFE.

A base layer BS may be disposed on the thin film encapsulation layer TFE. The base layer BS may include an inorganic insulating layer. At least one inorganic insulating layer may be provided on the thin film encapsulation layer TFE as the base layer BS.

The input sensing part ISP may include a first conductive pattern CTL1 and a second conductive pattern CTL2 disposed on the first conductive pattern CTL1. The first conductive pattern CTL1 may be disposed on the base layer BS. A first insulating layer TINS1 may be disposed on the base layer BS to cover the first conductive pattern CTL1. The first insulating layer TINS1 may include an inorganic insulating layer or an organic insulating layer.

The second conductive pattern CTL2 may be disposed on the first insulating layer TINS1. A second insulating layer TINS2 may be disposed on the first insulating layer TINS1 to cover the second conductive pattern CTL2. The second insulating layer TINS2 may include an organic insulating layer.

The first conductive pattern CTL1 and the second conductive pattern CTL2 may overlap the non-emissive area NPA. Although not illustrated, the first conductive pattern CTL1 and the second conductive pattern CTL2 may be disposed on the non-emissive area NPA between the emissive areas PA and may have a mesh shape.

The first conductive pattern CTL1 and the second conductive pattern CTL2 may form the sensors of the input sensing part ISP described above. For example, the first conductive pattern CTL1 and the second conductive pattern CTL2 having a mesh shape may be separated from each other in a certain area to form the sensors. A portion of the second conductive pattern CTL2 may be connected to the first conductive pattern CTL1.

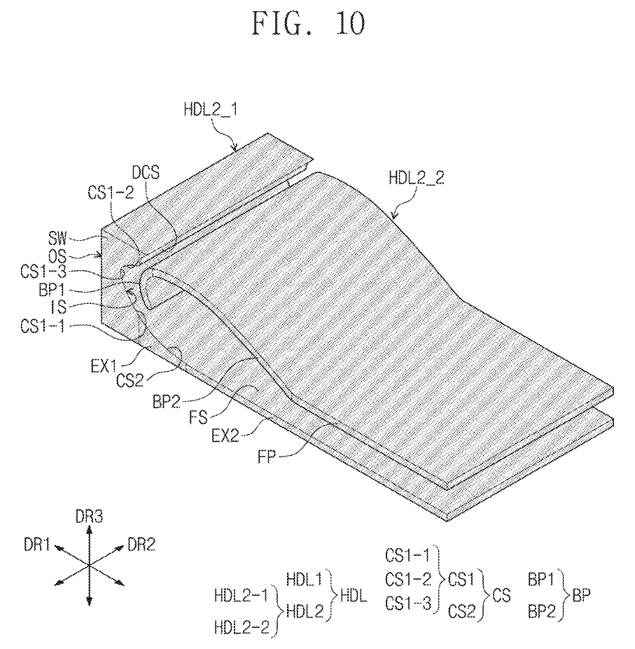

FIG. 9 is a sectional view taken along line III-III’ illustrated in FIG. 2, and illustrates a specific configuration of the second heat dissipating layer illustrated in FIG. 4. FIG. 10 is a perspective view of the second heat dissipating layer illustrated in FIG. 9.

For example, in FIG. 9, the display module DM and the first heat dissipating layer HDL1 are illustrated as a single layer, and the casing CAS is illustrated together with the heat dissipating layer HDL.

Referring to FIGS. 9 and 10, the second heat dissipating layer HDL2 may be disposed between the bottom portion BTP of the casing CAS and the first heat dissipating layer HDL1. The second heat dissipating layer HDL2 may extend in the first direction DR1. The second heat dissipating layer HDL2 may extend adjacent to the printed circuit board PCB.

The second heat dissipating layer HDL2 may include a second-first heat dissipating layer HDL2-1 and a second-second heat dissipating layer HDL2-2. Each of the second-first heat dissipating layer HDL2-1 and the second-second heat dissipating layer HDL2-2 may extend in the first direction DR1.

The second-first heat dissipating layer HDL2-1 and the second-second heat dissipating layer HDL2-2 may include a metal having a high thermal conductivity. For example, the second-first heat dissipating layer HDL2-1 and the second-second heat dissipating layer HDL2-2 may include a material such as gold, silver, copper, or aluminum. In an embodiment, all the portions of the second-first heat dissipating layer HDL2-1 and the second-second heat dissipating layer HDL2-2 may consist of a metal having a high thermal conductivity. Accordingly, the second-first heat dissipating layer HDL2-1 and the second-second heat dissipating layer HDL2-2 may perform a heat dissipation function. The second-first heat dissipating layer HDL2-1 and the second-second heat dissipating layer HDL2-2 may be coupled to the casing CAS and the first heat dissipating layer HDL1 by various coupling means such as an adhesive layer and a screw.

The second-first heat dissipating layer HDL2-1 may include a flat surface FS and a curved surface CS extending from the flat surface FS. The curved surface CS may have a concave shape. The flat surface FS may face toward the first heat dissipating layer HDL1, and the curved surface CS may be adjacent to one side of the first heat dissipating layer HDL1 and may face toward the inside of the second heat dissipating layer HDL2. The flat surface FS and the curved surface CS may be defined to form a hook shape.

The second-first heat dissipating layer HDL2-1 may include a sidewall SW, a first extension EX1, and a second extension EX2. For example, the boundaries between the sidewall SW and the first extension EX1, and between the first extension EX1 and the second extension EX2 are illustrated by dotted lines in FIG. 9.

The sidewall SW may be disposed between the lower surface of the first heat dissipating layer HDL1 and the bottom portion BTP of the casing CAS. The sidewall SW may contact the lower surface of the first heat dissipating layer HDL1 and the bottom portion BTP of the casing CAS. The sidewall SW may be adjacent to one side of the display module DM in the first direction DR1.

The sidewall SW may include an outer surface OS and an inner surface IS that face away from each other in the first direction DR1. The sidewall SW may extend in the second direction DR2. The outer surface OS may face toward the outside of the second heat dissipating layer HDL2, and the inner surface IS may face toward the inside of the second heat dissipating layer HDL2. The inner surface IS may have a concave curved shape. The outer surface OS may have a flat surface parallel to the second direction DR2 and the third direction DR3.

The first extension EX1 may extend from a portion of the sidewall SW in the first direction DR1. The first direction DR1 may be defined as a horizontal direction. For example, the first extension EX1 may extend from a lower portion of the sidewall SW in the first direction DR1.

The curved surface CS may be continuously defined on a portion of the inner surface IS and one surface of the first extension EX1 that extends from the portion of the inner surface IS. When the first extension EX1 extends from the lower portion of the sidewall SW, the one surface of the first extension EX1 may be defined as the upper surface of the first extension EX1. That is, the curved surface CS may be continuously defined on the portion of the inner surface IS and the upper surface of the first extension EX1.

The second extension EX2 may extend from the first extension EX1 in the first direction DR1. One surface of the second extension EX2 may be defined as the flat surface FS. When the first extension EX1 extends from the lower portion of the sidewall SW, the one surface of the second extension EX2 may be defined as the upper surface of the second extension EX2, and the upper surface of the second extension EX2 may be defined as the flat surface FS.

The curved surface CS may include a first curved surface CS1 and a second curved surface CS2 defined to be continuous with each other. The first curved surface CS1 may be defined to be concave from the portion of the inner surface IS toward the outer surface OS.

The first curved surface CS1 may include a first-first curved surface CS1-1, a first-second curved surface CS1-2, and a first-third curved surface CS1-3 that form a continuous curved surface. The first-first curved surface CS1-1 may be adjacent to the first extension EX1. The first-second curved surface CS1-2 may be disposed at a different height from the first-first curved surface CS1-1. For example, when the first extension EX1 extends from the lower portion of the sidewall SW, the first-second curved surface CS1-2 may be disposed in a higher position than the first-first curved surface CS1-1. The first-third curved surface CS1-3 may be defined between the first-first curved surface CS1-1 and the first-second curved surface CS1-2.

The curvature of the first-third curved surface CS1-3 may be greater than the curvature of the first-first curved surface CS1-1 and the curvature of the first-second curved surface CS1-2. That is, the first-third curved surface CS1-3 may be bent more than the first-first curved surface CS1-1 and the first-second curved surface CS1-2.

The second curved surface CS2 may be concavely defined on the one surface (e.g., the upper surface) of the first extension EX1 and may be defined to be continuous with the first-first curved surface CS1-1. The curvature of the first-third curved surface CS1-3 may be greater than the curvature of the second curved surface CS2. That is, the first-third curved surface CS1-3 may be bent more than the second curved surface CS2.

The first extension EX1 may have a gradually decreasing thickness farther away from the sidewall SW. The second extension EX2 may have a thickness equal to the minimum thickness of the first extension EX1. An end of the second extension EX2 may be adjacent to the printed circuit board PCB. The first extension EX1 and the second extension EX2 may contact the bottom portion BTP of the casing CAS.

The inner surface IS may include a dummy curved surface DCS that bends and extends from the first-second curved surface CS1-2 and that is disposed at a different height from the curved surface CS. When the first extension EX1 extends from the lower portion of the sidewall SW, the dummy curved surface DCS may be disposed in a higher position than the curved surface CS. The dummy curved surface DCS may be adjacent to the first heat dissipating layer HDL1.

The second-second heat dissipating layer HDL2-2 may be disposed over the flat surface FS, the first-first curved surface CS1-1, and the second curved surface CS2. The second-second heat dissipating layer HDL2-2 may include a flat portion FP and a bending portion BP extending from the flat portion FP. The flat portion FP may face the flat surface FS. The bending portion BP may extend from the flat portion FP toward the curved surface CS.

The flat portion FP and the bending portion BP may be defined to form a hook shape. The hook shape defined by the flat portion FP and the bending portion BP and the hook shape defined by the curved surface CS and the flat surface FS may be roughly symmetrical to each other in the third direction DR3.

The gap between an end of the curved surface CS and a portion of the bending portion BP closest to the end of the curved surface CS may be defined as a first gap GP1. The gap between an end of the flat surface FS and an end of the flat portion FP may be defined as a second gap GP2. The first gap GP1 may be smaller than the second gap G2. The space defining the first gap GP1 may be defined as an outlet OT, and the space defining the second gap GP2 may be defi6ned as an inlet IT.

The bending portion BP may include a first bending portion BP1 and a second bending portion BP2 extending from the first bending portion BP1. For example, the boundaries between the first bending portion BP1, the second bending portion BP2, and the flat portion FP are illustrated by dotted lines in FIG. 9.

The first bending portion BP1 may be bent toward the sidewall SW. The first bending portion BP1 may face the first-third curved surface CS1-3 and may be bent toward the first-third curved surface CS1-3. The second bending portion BP2 may extend from the first bending portion BP1 toward the flat portion FP. When the first extension EX1 extends from the lower portion of the sidewall SW, the second bending portion BP2 may be bent upward toward the first heat dissipating layer HDL1.

In an embodiment of the present disclosure, the first heat dissipating layer HDL1 and the second heat dissipating layer HDL2 may perform a heat dissipation function together to effectively dissipate heat generated from the display module DM. In addition, the sidewall SW may contact the first heat dissipating layer HDL1 and the casing CAS, and thus the heat may be more effectively dissipated through the first heat dissipating layer HDL1, the sidewall SW, and the casing CAS including a metal.

Airflow may be generated by the second-first heat dissipating layer HDL2-1 and the second-second heat dissipating layer HDL2-2. The airflow may be generated by the following principle. For example, the airflow is illustrated by a dotted arrow in FIG. 9.

The user of the electronic device ED may move the electronic device ED in various directions to use the electronic device ED. For example, the electronic device ED may be moved in the first direction DR1, the second direction DR2, and the third direction DR3 and may be turned upside down. In this case, air in the space between the first heat dissipating layer HDL1 and the bottom portion BTP may move. In addition, a convection phenomenon may occur due to the heat generated from the display module DM, and therefore the air in the space between the first heat dissipating layer HDL1 and the bottom portion BTP may move.

The air may be injected into the inlet IT where the second gap GP2 is defined. The air may move from the flat surface FS to the curved surface CS. According to Bernoulli’s principle, the velocity of the air moving along the curved surface CS may be higher than the velocity of the air moving along the flat surface FS. In addition, since the gap (e.g., first gap GP1) of the outlet OT is narrower than the gap (e.g., second gap GP2) of the inlet IT, the velocity of the air moving along the curved surface CS may be increased at the outlet OT, and the air may be discharged into the space between the first heat dissipating layer HDL1 and the second-second heat dissipating layer HDL2-2.

Airflow AF depending on the difference in air velocity may be formed by the second-first heat dissipating layer HDL2-1 and the second-second heat dissipating layer HDL2-2. The airflow AF may cool the heat dissipating layer HDL. That is, since the airflow AF is formed by the second-first heat dissipating layer HDL2-1 and the second-second heat dissipating layer HDL2-2, more heat may be dissipated.

According to an embodiment of the present disclosure, the first heat dissipating layer HDL1 and the second heat dissipating layer HDL2 may perform a heat dissipation function together, and thus the heat dissipation performance of the display device DD may be improved. In addition, the second heat dissipating layer HDL2 may circulate air even without a fan for air circulation so that heat may be additionally dissipated by the circulating air, and thus the heat dissipation performance of the display device DD may be further improved.

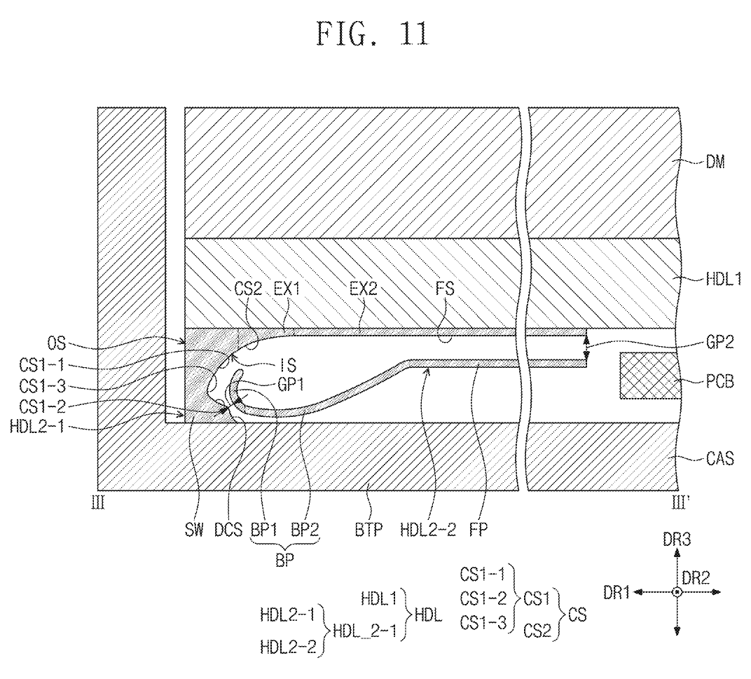

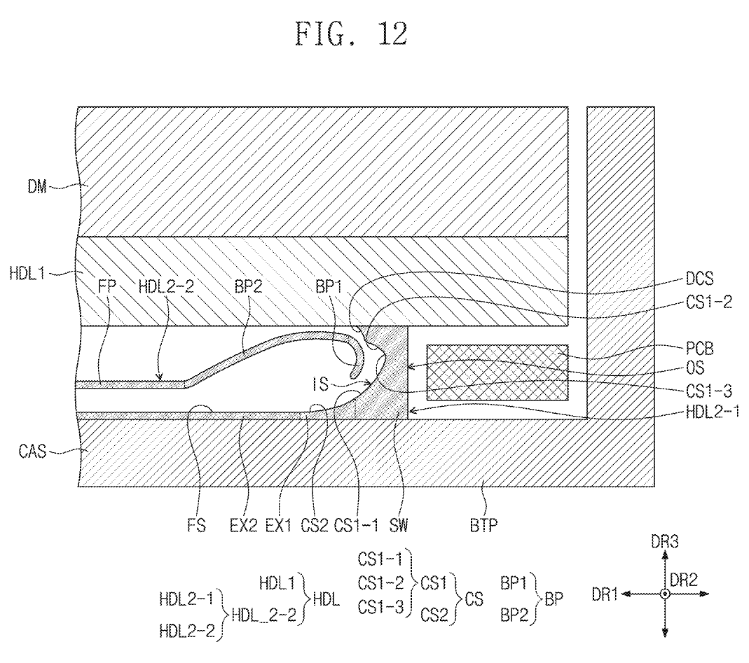

FIG. 11 is a view illustrating a configuration of a second heat dissipating layer according to an embodiment of the present disclosure.

For example, FIG. 11 is a sectional view corresponding to FIG. 9. Hereinafter, the components illustrated in FIG. 11 will be described focusing on the difference from the configuration illustrated in FIG. 9.

Referring to FIG. 11, the second heat dissipating layer HDL_2-1 may have a shape obtained by turning the second heat dissipating layer HDL2 illustrated in FIG. 9 upside down in the third direction DR3. Accordingly, a first extension EX1 may extend from an upper portion of a sidewall SW. In addition, one surface of the first extension EX1 on which a second curved surface CS2 is defined may be defined as the lower surface of the first extension EX1, and a flat surface FS of a second extension EX2 may be defined as the lower surface of the second extension EX2. The second curved surface CS2 may be concavely defined on the one surface (e.g., the lower surface) of the first extension EX1. Therefore, the air may be discharged into the space between the bottom portion BTP of the casing CAS and the second-second heat dissipating layer HDL2-2.

The first extension EX1 and the second extension EX2 may contact the lower surface of the first heat dissipating layer HDL1. When the first extension EX1 extends from the upper portion of the sidewall SW, a first-second curved surface CS1-2 may be disposed in a lower position than a first-first curved surface CS1-1. In addition, a dummy curved surface DCS may be adjacent to the bottom portion BTP of the casing CAS.

A second-second heat dissipating layer HDL2-2 may be disposed under the flat surface FS, the first-first curved surface CS1-1, and the second curved surface CS2. When the first extension EX1 extends from the upper portion of the sidewall SW, a second bending portion BP2 may be bent downward toward the bottom portion BTP of the casing CAS.

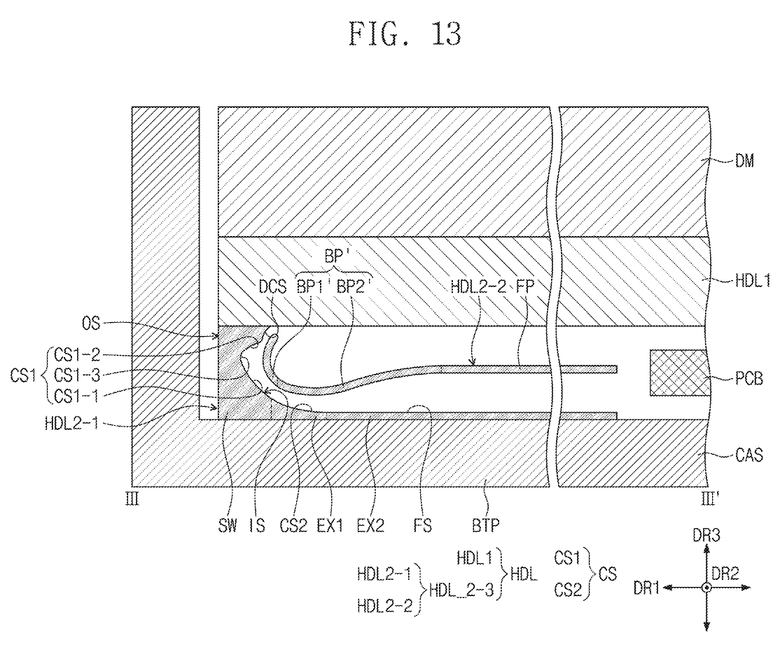

FIG. 12 is a view illustrating a configuration of a second heat dissipating layer according to an embodiment of the present disclosure.

For example, FIG. 12 illustrates a cross-section of the portion of the electronic device ED where the printed circuit board PCB is disposed, and for convenience of description, the flexible circuit board FPCB and the data driver DDV are omitted. Hereinafter, the components illustrated in FIG. 12 will be described focusing on the difference from the configuration illustrated in FIG. 9.

Referring to FIG. 12, the second heat dissipating layer HDL_2-2 may be disposed to be symmetrical to the second heat dissipating layer HDL2 illustrated in FIG. 9 in the first direction DR1. For example, although the sidewall SW in FIG. 9 is disposed adjacent to one side of the display module DM where the printed circuit board PCB is not disposed, a sidewall SW in FIG. 12 may be adjacent to the printed circuit board PCB. In addition, a second bending portion BP2 may also be disposed adjacent to the printed circuit board PCB.

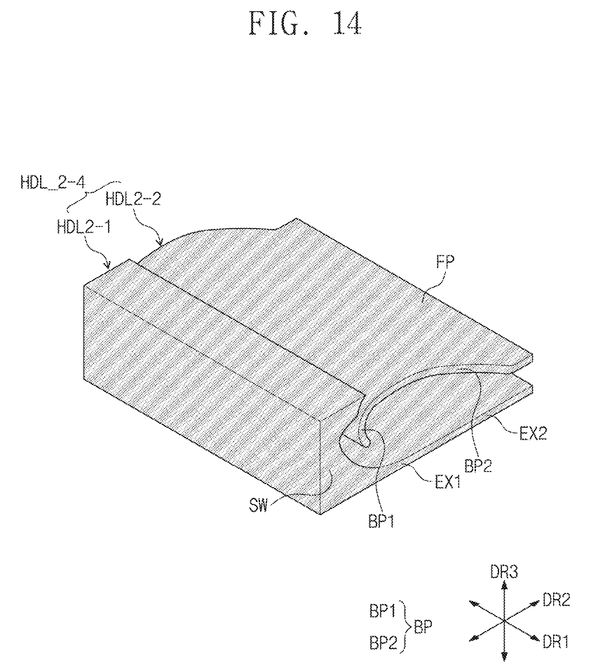

FIG. 13 is a view illustrating a configuration of a second heat dissipating layer according to an embodiment of the present disclosure.

For example, FIG. 13 is a sectional view corresponding to FIG. 9. Hereinafter, the components illustrated in FIG. 13 will be described focusing on the difference from the configuration illustrated in FIG. 9.

Referring to FIG. 13, a second-second heat dissipating layer HDL2-2’ of the second heat dissipating layer HDL_2-3 may have a shape obtained by turning the second-second heat dissipating layer HDL2-2 illustrated in FIG. 9 upside down in the third direction DR3. A first bending portion BP1’ of the second-second heat dissipating layer HDL2-2’ may be bent toward a first-third curved surface CS1-3, and a second bending portion BP2’ of the second-second heat dissipating layer HDL2-2’ may be bent downward toward the bottom portion BTP.

FIG. 14 is a view illustrating a configuration of a second heat dissipating layer according to an embodiment of the present disclosure.

For example, FIG. 14 is a perspective view corresponding to FIG. 10. Hereinafter, the components illustrated in FIG. 14 will be described focusing on the difference from the configuration illustrated in FIG. 10.

Referring to FIG. 14, although the sidewall SW in FIGS. 9 and 10 is disposed to face in the first direction DR1, a sidewall SW of the second heat dissipating layer HDL_2-4 in FIG. 14 may be disposed to face in the second direction DR2. Accordingly, the sidewall SW may be adjacent to one side of the display module DM (illustrated in FIG. 2) in the second direction DR2. A first extension EX1 may extend from the sidewall SW in the second direction DR2, and a second extension EX2 may extend from the first extension EX1 in the second direction DR2.

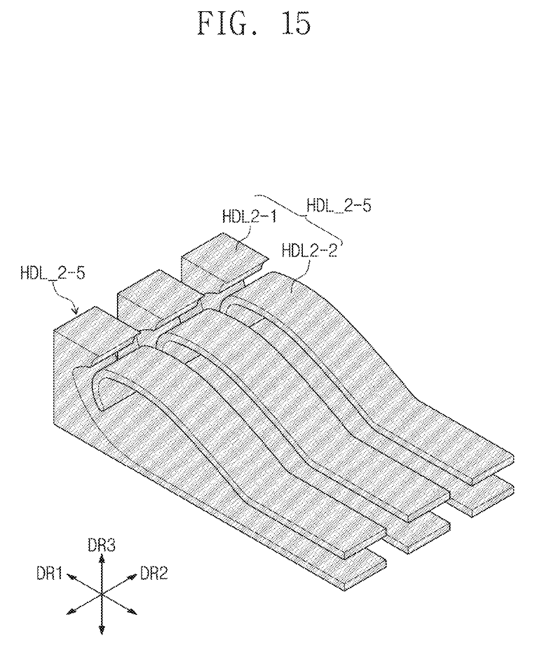

FIG. 15 is a view illustrating a configuration of a second heat dissipating layer according to an embodiment of the present disclosure.

For example, FIG. 15 is a perspective view corresponding to FIG. 10. Hereinafter, the components illustrated in FIG. 15 will be described focusing on the difference from the configuration illustrated in FIG. 10.

Referring to FIG. 15, a plurality of heat dissipating layers HDL_2-5 may be disposed under the display module DM described above. The heat dissipating layers HDL_2-5 may extend in the first direction DR1 and may be arranged in the second direction DR2.

According to the embodiments of the present disclosure, the first heat dissipating layer may be disposed under the display module, and the second heat dissipating layer may be disposed under the first heat dissipating layer. The first heat dissipating layer and the second heat dissipating layer may perform a heat dissipation function together, thereby improving the heat dissipation performance of the display device. In addition, the second heat dissipating layer may circulate air so that heat may be additionally dissipated by the circulating air, and thus the heat dissipation performance of the display device may be further improved.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display module;
a first heat dissipating layer disposed under the display module; and
a second heat dissipating layer disposed under the first heat dissipating layer,
wherein the second heat dissipating layer includes:
a second-first heat dissipating layer including a flat surface and a curved surface extending from the flat surface, the curved surface being concave; and
a second-second heat dissipating layer including a flat portion facing the flat surface and a bending portion extending from the flat portion toward the curved surface, and
wherein a first gap between an end of the curved surface and a portion of the bending portion closest to the end of the curved surface is smaller than a second gap between an end of the flat surface and an end of the flat portion,
wherein the second-first heat dissipating layer and the second-second heat dissipating layer include a metal.

2. The display device of claim 1, wherein the second-first heat dissipating layer further includes:
a sidewall including an outer surface and an inner surface;
a first extension extending from a portion of the sidewall in a first direction defined as a horizontal direction; and
a second extension extending from the first extension in the first direction, the second extension having the flat surface, and
wherein the curved surface is continuously defined on a portion of the inner surface and one surface of the first extension extending from the portion of the inner surface.

3. The display device of claim 2, wherein the curved surface includes a first curved surface defined to be concave from the portion of the inner surface toward the outer surface.

4. The display device of claim 3, wherein the first curved surface includes:
a first-first curved surface adjacent to the first extension;
a first-second curved surface disposed at a different height from the first-first curved surface; and
a first-third curved surface between the first-first curved surface and the first-second curved surface, and
wherein the first-third curved surface has a greater curvature than each of the first-first curved surface and the first-second curved surface.

5. The display device of claim 4, wherein the curved surface further includes a second curved surface concavely defined on the one surface of the first extension and defined to be continuous with the first-first curved surface, and
wherein the first-third curved surface has a greater curvature than the second curved surface.

6. The display device of claim 4, wherein the inner surface includes a dummy curved surface extending and bent from the first-second curved surface and disposed at a different height from the curved surface.

7. The display device of claim 2, wherein the first extension has a gradually decreasing thickness farther away from the sidewall, and the second extension has a thickness equal to a minimum thickness of the first extension.

8. The display device of claim 2, wherein the sidewall is disposed between a lower surface of the first heat dissipating layer and a bottom portion of a casing disposed under the second heat dissipating layer and contacts with the lower surface of the first heat dissipating layer and the bottom portion of the casing.

9. The display device of claim 8, wherein the first extension extends from a lower portion of the sidewall, the one surface of the first extension is defined as an upper surface of the first extension, and the flat surface of the second extension is defined as an upper surface of the second extension.

10. The display device of claim 9, wherein the first extension and the second extension contact the bottom portion of the casing.

11. The display device of claim 8, wherein the first extension extends from an upper portion of the sidewall, the one surface of the first extension is defined as a lower surface of the first extension, and the flat surface of the second extension is defined as a lower surface of the second extension.

12. The display device of claim 11, wherein the first extension and the second extension contact the lower surface of the first heat dissipating layer.

13. The display device of claim 2, wherein the bending portion includes:
a first bending portion adjacent to the sidewall and bent toward the sidewall; and
a second bending portion extending from the first bending portion to the flat portion.

14. The display device of claim 13, wherein the second bending portion is bent toward the first heat dissipating layer.

15. The display device of claim 13, wherein the second bending portion is bent toward a bottom portion of a casing disposed under the second heat dissipating layer.

16. The display device of claim 2, wherein the display module includes:
a display panel; and
a printed circuit board connected to the display panel and disposed under the display panel, and
wherein the sidewall is adjacent to the printed circuit board.

17. The display device of claim 1, wherein the first heat dissipating layer includes:
a base layer;
a heat dissipating film disposed under the base layer; and
a shielding layer disposed under the heat dissipating film.

18. An electronic device comprising:
a camera;
a display device, which displays an image obtained by the camera; and
a casing, which accommodates the camera and the display device,
wherein the display device includes:
a display module;
a first heat dissipating layer disposed under the display module; and
a second heat dissipating layer disposed under the first heat dissipating layer,
wherein the second heat dissipating layer includes:
a second-first heat dissipating layer including a flat surface and a curved surface extending from the flat surface, the curved surface being concave; and
a second-second heat dissipating layer including a flat portion facing the flat surface and a bending portion extending from the flat portion toward the curved surface, and
wherein a first gap between an end of the curved surface and a portion of the bending portion closest to the end of the curved surface is smaller than a second gap between an end of the flat surface and an end of the flat portion,
wherein the second-first heat dissipating layer and the second-second heat dissipating layer include a metal.

19. The electronic device of claim 18, wherein the second-first heat dissipating layer further includes:
a sidewall including an outer surface and an inner surface;
a first extension extending from a portion of the sidewall in a first direction defined as a horizontal direction; and
a second extension extending from the first extension in the first direction, the second extension having the flat surface,
wherein the curved surface is continuously defined on a portion of the inner surface and one surface of the first extension extending from the portion of the inner surface, and
wherein the sidewall is disposed between a lower surface of the first heat dissipating layer and a bottom portion of the casing and contacts with the lower surface of the first heat dissipating layer and the bottom portion of the casing.
